(19) United States
(12) Patent Application Publication
(10) Pub. No.: US 2015/0136950 A1
(43) Pub. Date: May 21, 2015

(54) TWO IMAGER PROJECTION DEVICE

(71) Applicant: 3M INNOVATIVE PROPERTIES COMPANY, St. Paul, MN (US)

(72) Inventors: Joseph C. Carls, Austin, TX (US); Craig R. Schardt, Woodbury, MN (US); Duane E. Preiss, Austin, TX (US); Dwight G. Baldwin, Austin, TX (US)

(73) Assignee: 3M INNOVATIVE PROPERTIES COMPANY, ST. PAUL, MN (US)

(21) Appl. No.: 14/395,941

(22) PCT Filed: Apr. 11, 2013
(86) PCT No.: PCT/US2013/036067

§ 371 Date: Oct. 21, 2014

Related U.S. Application Data
(60) Provisional application No. 61/637,939, filed on Apr. 25, 2012.

(51) Int. Cl. H01L 27/146

(52) U.S. Cl. CPC H01L 27/14665
USPC 250/208.1

(57) ABSTRACT

The present disclosure describes optical elements and optical devices that use the optical elements to allow the output of two imagers to be combined onto a single optical axis. Each of the two imagers can be based on alternate polarization directions, and the disclosed embodiments can enable high contrast 3D projectors without requiring either time or polarization sequencing. The present disclosure further describes projection systems that include the optical devices.

### RELATED APPLICATION

This application is related to the following U.S. patent application, which is incorporated by reference: TWO IMAGER PROJECTION DEVICE, Attorney Docket No. 68312US002, filed on an even date herewith.

### BACKGROUND

3D video is becoming popular in consumer electronics. This is largely due to the increasing popularity of 3D cinema. However none of the existing implementations of 3D video are completely satisfactory. One popular approach, using time sequencing of the left and right images, employs active shutter glasses to extract the stereo image out of the time domain. One problem with this approach is that each eye only sees light half of the time, leading to a diminished perceived brightness. Another problem is that the active shuttering can lead to the perception of flicker in the image which can result in eye fatigue or other physical symptoms. In order to eliminate flicker, the imagers must be operated at high frequencies in order to blur out the modulation. This increases the technical requirements and cost of the imagers. In addition, the active shutter glasses can be quite expensive and are generally not suitable for large audiences.

A second approach, popularized by Real-D Cinema Systems, is to use polarized light to present two different images to the eyes, one polarization for the left eye and the second polarization for the right eye. In the Real-D approach, the light is circularly polarized in order to minimize the impact of rotations of the face around the viewing axis. One advantage of the Real-D process is that it uses passive glasses, and the lenses of the glasses need only be circularly polarized in an opposite sense to one another. Typically in the Real-D process, either two separate projectors are used and the outputs separately circularly polarized, or a single projector is used and in a time sequential manner the output is polarized with alternate circular polarizations. One disadvantage of the Real-D system is that half of the light is lost: in the first case two projectors are required but one polarization from each is discarded, and in the second case half of the light is lost since one polarization is discarded in a time sequential fashion.

A third approach, by Dolby Laboratories and others, uses two sets of additive primary colors, one for each eye to create the stereo image. A set of passive glasses, each lens of which transmits only the appropriate set of additive primaries is provided to separate out the stereo images for the viewer. One disadvantage of this approach is that the optical efficiency can be rather low, or the complexity of the projector is rather high.

### SUMMARY

The present disclosure describes optical elements and optical devices that use the optical elements to allow the output of two imagers to be combined onto a single optical axis. Each of the two imagers can be based on alternate polarization directions, and the disclosed embodiments can enable high contrast 3D projectors without requiring either time or polarization sequencing. The present disclosure further describes projection systems that include the optical devices. In one aspect, the present disclosure provides an imaging device that includes a first polarizing beam splitter (PBS) having an output surface and a first reflective polarizer aligned to a first polarization direction, a second PBS having a first imager surface and a second reflective polarizer aligned to an orthogonal second polarization direction, and a third PBS having an input surface and a third reflective polarizer aligned to the second orthogonal polarization direction. The imaging device further includes a fourth PBS having a second imager surface and a fourth reflective polarizer aligned to the first polarization direction, the first through fourth PBS arranged such that the first through fourth reflective polarizers are aligned in an X shape, the first imager surface adjacent the input surface, and the second imager surface opposite the output surface; a first imager disposed facing the first imager surface; and a second imager disposed facing the second imager surface, wherein an unpolarized input light entering the input surface exits the output surface as a first imaged light having the first polarization direction and a second imaged light having the second orthogonal polarization direction. In another aspect, the present disclosure provides a projection system that includes the imaging device, an input light source capable of injecting light into the input surface, and projection optics disposed to project light exiting from the output surface to a projection screen.

In yet another aspect, the present disclosure provides an imaging device that includes a first polarizing beam splitter (PBS) having an output surface and a first reflective polarizer; a second PBS having a first imager surface, a second reflective polarizer, and a first adjacent half-wave retarder; a third PBS having an input surface and a third reflective polarizer; and a fourth PBS having a second imager surface, a fourth reflective polarizer, and a second adjacent half-wave retarder. The first through fourth PBS are arranged such that the first through fourth reflective polarizers are each aligned to a first polarization direction and form an X shape, the first imager surface adjacent the input surface, and the second imager surface opposite the output surface; a first imager disposed facing the first imager surface; and a second imager disposed facing the second imager surface, wherein an unpolarized input light entering the input surface, exits the output surface as a second imaged light having the first polarization direction and a first imaged light having a second polarization direction orthogonal to the first polarization direction. In yet another aspect, the present disclosure provides a projection system that includes the imaging device, an input light source capable of injecting light into the input surface, and projection optics disposed to project light exiting from the output surface to a projection screen.

In yet another aspect, the present disclosure provides an imaging device that includes a first polarizing beam splitter (PBS) having an output surface and a first reflective polarizer; a second PBS having a first imager surface, a second reflective polarizer, and a first adjacent half-wave retarder; and a third PBS having an input surface, a third reflective polarizer, and a second adjacent half-wave retarder. The imaging device further includes a fourth PBS having a second imager surface and a fourth reflective polarizer, wherein the first through fourth PBS are arranged such that the first through fourth reflective polarizers are each aligned to a first polarization direction and form an X shape, the first imager surface adjacent the output surface, and the second imager surface opposite the output surface. The imaging device still further includes a first imager disposed facing the first imager surface; and a second imager disposed facing the second imager surface, wherein an unpolarized input light entering the input surface, exits the output surface as a second imaged light having the first polarization direction and a first imaged light having a second polarization direction orthogonal to the first polarization direction. In yet another aspect, the present disclosure provides a projection system that includes the imaging device, an input light source capable of injecting light into the input surface, and projection optics disposed to project light exiting from the output surface to a projection screen.

The above summary is not intended to describe each disclosed embodiment or every implementation of the present disclosure. The figures and the detailed description below more particularly exemplify illustrative embodiments.

### BRIEF DESCRIPTION OF THE DRAWINGS

Throughout the specification reference is made to the appended drawings, where like reference numerals designate like elements, and wherein:

FIG. 1 shows a cross-sectional schematic of a two imager projector;

FIG. 2 shows a cross-sectional schematic of a two imager projector; and

FIG. 3 shows a cross-sectional schematic of a two imager projector.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

It would be extremely useful to have a device that enables high contrast 3-D projection without requiring time sequencing or multiple projectors. The present disclosure describes optical elements and optical devices that use the optical elements to allow the output of two imagers to be combined onto a single optical axis. Each of the two imagers can be based on alternate polarization directions, and the disclosed embodiments can enable high contrast 3D projectors without requiring either time or polarization sequencing. The present disclosure further describes projection systems that include the optical devices. In some cases, however, time and/or polarization sequencing can be layered upon the described optical device to provide enhancements that were not possible with prior approaches, as described elsewhere. The disclosed embodiments effectively double the brightness of the optical device compared to conventional approaches. The construction can further eliminate issues with low contrast that are associated with prior approaches.

In one particular embodiment, an array of 4 polarizing beam splitters (PBSs) can be used in the two imager projection device, such as a two Liquid Crystal on Silicon (LCOS) projector. The 4-PBS array is arranged such that the reflective polarizers in each PBS are aligned in an X shape that separates input light into two distinct polarization directions using crossed reflective polarizers, routes each polarization direction to one of two imagers, re-combines the light reflected from the imager and presents the resulting light to a projection lens.

In one particular embodiment, the present disclosure can enable low-cost, high contrast 3D projection without time sequencing (and the attendant cost and disadvantage of active shutter glasses) and without the high equipment cost of other polarization based technologies. The disclosure can use reflective polarizers such as 3M Multilayer Optical Film (MOF) polarizers, which have sufficiently high reflection and transmission properties to enable an efficient device.

In another particular embodiment, identical content can be projected onto each of the two imagers, which can serve to effectively double the brightness of the projector and permit the use of both polarizations without the use of a polarization converting system. This can enable the use of larger LEDs and further increase the brightness achievable in the projector.

In yet another particular embodiment, two different video contents (one on each polarization state) can be imaged and projected onto a single screen. In this embodiment, two separate pairs of polarized glasses can be used by different viewers, each pair transmitting only a single polarization state to separate out the different content. This embodiment can enable two different viewers to view two different video contents at the same time on the same screen.

In yet another particular embodiment, two different video contents, each having one of two orthogonal polarization states, can be projected onto a reflective polarizer, thereby separating the two contents so that they can be displayed separately, for example, side-by-side or one on top of the other.

In yet another particular embodiment, time sequencing and active goggles (that is, shutter glasses) can be combined with the disclosed device, so that two different 3D contents can be projected simultaneously by the same device on to the same (or, in combination with the above embodiment, different) screens.

Some embodiments of polarization-based 3D projectors use a single polarizing beam splitter (PBS), feeding illumination light via one face, splitting the light into two polarizations off of the PBS, transmitting the light to two different imagers located on two additional side surfaces, and then recombining the light on the PBS and allowing the light to exit the PBS through the fourth face where it enters the projection lens. However, this embodiment suffers from significantly impaired contrast due to reflection of dark-state p-polarization into the projection lens. This generally can limit the contrast of single PBS 3D systems to about 25:1, which may be unacceptable for some applications. In addition, depending on the reflective polarizer technology used, there can be significant differences between the efficiency of the transmitted polarization compared to the reflected polarization. This can be especially the case if the required polarization directions do not correspond to the defined s- and p-polarization directions associated with the reflective polarizer.

In contrast to typical polarization based 3D projectors, the embodiments described herein each use multiple polarizing beam splitters (PBSs). It should be understood that any conventional reflective polarizer technology may be used in the embodiments described herein. However, reflective polarizers based on multilayer optical film (MOF) are particularly advantageous because of their high efficiency and ability to operate at low F/#.

In some cases, the reflective polarizer can be a Cartesian reflective polarizer or a non-Cartesian reflective polarizer. A non-Cartesian reflective polarizer can include multilayer inorganic films such as those produced by sequential deposition of inorganic dielectrics, such as a MacNeille polarizer. A Cartesian reflective polarizer has a polarization axis state, and includes both wire-grid polarizers and polymeric multilayer optical films (MOF) such as can be produced by extrusion and subsequent stretching of a multilayer polymeric laminate. A Cartesian reflective polarizer film provides the polarizing beam splitter with an ability to pass input light rays that are not fully collimated, and that are divergent or skewed from a central light beam axis, with high efficiency. The Cartesian reflective polarizer film can comprise a polymeric multilayer optical film that comprises multiple layers of dielectric or polymeric material. Use of dielectric films can have the advantage of low attenuation of light and high efficiency in passing light. The multilayer optical film can comprise polymeric multilayer optical films such as those described in U.S. Pat. No. 5,962,114 (Jonza et al.) or U.S. Pat. No. 6,721,096 (Bruzzone et al.).

In some embodiments, a retarder, such as a half-wave retarder, can placed adjacent a reflective polarizer to effect different polarization states being reflected or transmitted from the polarizer/retarder assembly. In some cases, a retarder, such as a quarter-wave retarder, can be positioned adjacent to an imager, to effect rotation of the polarization direction of incident light upon reflection from the imager. According to one aspect, the retarder is a quarter-wave retarder aligned at approximately 45 degrees to a polarization direction of the reflective polarizer. In one embodiment, the alignment can be from 35 to 55 degrees; from 40 to 50 degrees; from 43 to 48 degrees; or from 44.5 to 45.5 degrees to a polarization direction of the reflective polarizer. In one particular embodiment, when the incident light intercepts the quarter-wave retarder and the reflective polarizer at approximately 45 degrees, it can be preferable to have the quarter-wave retarder aligned instead at approximately 53 degrees to the polarization direction of the reflective polarizer.

In some embodiments, each of the reflective polarizers described herein can instead be a reflective polarizer laminate that includes a second reflective polarizer disposed adjacent to a first reflective polarizer, with both reflective polarizers aligned to pass the same polarization direction of light. In some embodiments, each of the reflective polarizer laminates can further include an absorbing polarizer disposed between the two reflective polarizers, also aligned to the same polarization direction. The use of multiple reflective polarizers disposed adjacent each other, either with or without an absorptive polarizer sandwiched therebetween, can dramatically improve the contrast of the projection devices described herein.

For the purposes of the description provided herein, the term “aligned to a desired polarization state” or “aligned to a desired polarization direction” is intended to associate the alignment of the pass axis of an optical element to a desired polarization state of light that passes through the optical element, that is, a desired polarization state such as s-polarization, p-polarization, right-circular polarization, left-circular polarization, or the like. In one embodiment described herein with reference to the Figures, an optical element such as a polarizer aligned to the first polarization state means the orientation of the polarizer that passes the p-polarization state of light, and reflects or absorbs the second polarization state (in this case the s-polarization state) of light. It is to be understood that the polarizer can instead be aligned to pass the s-polarization state of light, and reflect or absorb the p-polarization state of light, if desired.

Also for the purposes of the description provided herein, the term “facing” refers to one element disposed so that a perpendicular line from the surface of the element follows an optical path that is also perpendicular to the other element. One element facing another element can include the elements disposed adjacent each other. One element facing another element further includes the elements separated by optics so that a light ray perpendicular to one element is also perpendicular to the other element.

In some cases, a polarization component of an input light can pass through to a polarization rotating reflector. The polarization rotating reflector reverses the propagation direction of the light and alters the magnitude of the polarization components, depending of the type and orientation of a retarder disposed in the polarization rotating reflector. The polarization rotating reflector can be used to simply reflect light, such as with a mirror, and can also be used to impart information, such as an image, to the input light which can results in an imaged light output. As such, the polarization rotating reflector can include a liquid crystal imager, a liquid crystal on silicon (LCoS) imager, a digital micromirror imager, a broadband mirror, a wavelength-selective mirror such as a dichroic filter, and a retarder. The retarder can provide any desired retardation, such as an eighth-wave retarder, a quarter-wave retarder, and the like, although quarter-wave retarders can be advantageously used. Linearly polarized light is changed to circularly polarized light as it passes through a quarter-wave retarder aligned at an angle of 45° to the axis of light polarization. In contrast, linearly polarized light is changed to a polarization state partway between s-polarization and p-polarization (either elliptical or linear) as it passes through other retarders and orientations, and can result in a lower efficiency of light transport within an optical device. In some cases, however, different retardation (for example, half-wave retardation) may be combined with different orientations (for example, 22.5 degrees or the like) may be envisioned that can result in a similar efficiency, if desired.

Several different light sources can be used to illuminate the projector, including one or more light emitting diodes (LED's), lasers, laser diodes, organic LED's (OLED's), and non solid state light sources such as ultra high pressure (UHP) mercury, halogen or xenon lamps with appropriate collectors or reflectors. Liquid Crystal on Silcon (LCoS)-based portable projection systems are becoming common due to the availability of low cost and high resolution LCoS panels. In one particular example, a list of elements in an LED-illuminated LCoS projector may include LED light source or sources, optional color combiner, relay optics, PBS, LCoS panels, and projection lens unit.

In some cases, a micromirror array such as a DLP® imager available from Texas Instruments can be used as the imager to form an image for the projector. In the DLP® imager, individual mirrors within the digital micro-mirror array represent individual pixels of the projected image. In some cases, particularly when using polarized light to illuminate the micromirror array, it may be desirable to rotate the polarization direction of the incident and reflected light by using a retarder, such as a quarter-wave retarder, such that light having a first polarization direction directed toward the imager is rotated to an orthogonal second polarization direction upon reflection from the imager, as described elsewhere. The quarter-wave retarder can be aligned at an angle, such as about 45 degrees, to a desired polarization direction, as described elsewhere.

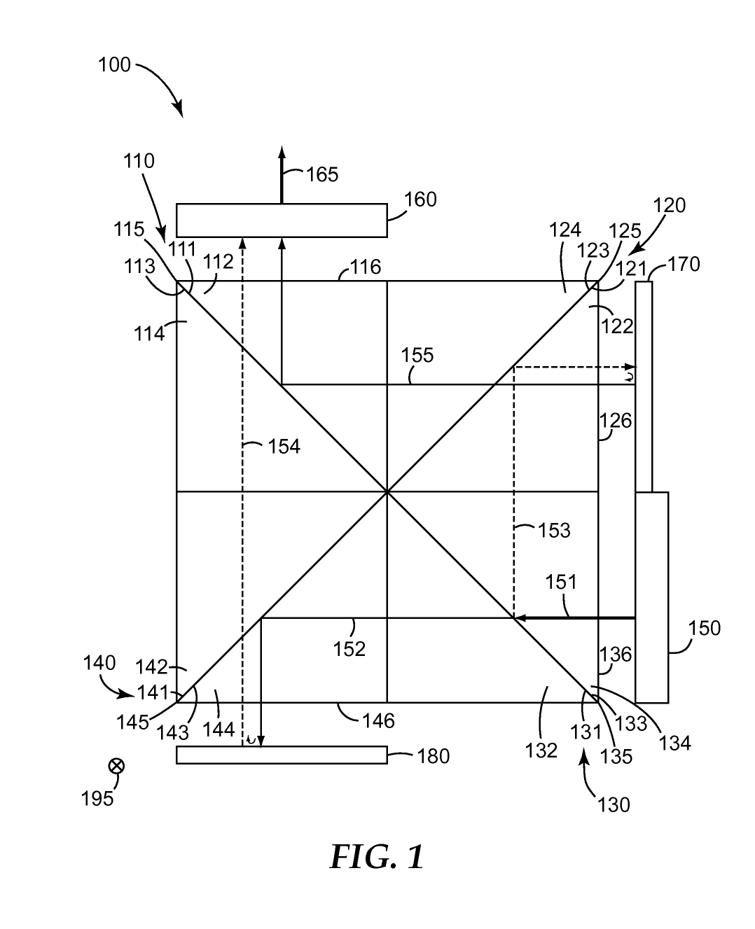

FIG. 1 shows a cross-sectional schematic of a two imager projector 100 according to one aspect of the disclosure. Projector 100 includes a first polarizing beam splitter (PBS) 110 that includes a first prism 112 having a first diagonal surface 111 and an output surface 116, a second prism 114 having a second diagonal surface 113, and a first reflective polarizer 115 disposed between the first diagonal surface 111 and the second diagonal surface 113. The first reflective polarizer 115 is aligned to a first polarization direction 195. In the embodiment shown in FIG. 1, the first polarization direction 195 is shown to be perpendicular to the page, and aligned to the first polarization direction 195 is intended to mean that the first reflective polarizer 115 is aligned to pass s-polarized light and reflect p-polarized light, as described elsewhere.

Projector 100 further includes a second PBS 120 that includes a third prism 122 having a third diagonal surface 121 and a first imager surface 126, a fourth prism 124 having a fourth diagonal surface 123, and a second reflective polarizer 125 disposed between the third diagonal surface 121 and the fourth diagonal surface 123. The second reflective polarizer 125 is aligned to an orthogonal second polarization direction, such that p-polarized light passes through the second reflective polarizer 125 and s-polarized light reflects from the second reflective polarizer 125, as described elsewhere.

Projector 100 still further includes a third PBS 130 that includes a fifth prism 132 having a fifth diagonal surface 131, a sixth prism 134 having a sixth diagonal surface 133, an input surface 136, and a third reflective polarizer 135 disposed between the fifth diagonal surface 131 and the sixth diagonal surface 133. The third reflective polarizer 135 is aligned to the orthogonal second polarization direction, such that p-polarized light passes through the third reflective polarizer 135 and s-polarized light reflects from the third reflective polarizer 135, as described elsewhere.

Projector 100 still further includes a fourth PBS 140 that includes a seventh prism 142 having a seventh diagonal surface 141, an eighth prism 144 having a eighth diagonal surface 143, a second imager surface 146, and a fourth reflective polarizer 145 disposed between the seventh diagonal surface 141 and the eighth diagonal surface 143. The fourth reflective polarizer 145 is aligned to the first polarization direction such that s-polarized light passes through the fourth reflective polarizer 145 and p-polarized light reflects from the fourth reflective polarizer, as described elsewhere. The first, second, third, and fourth PBS 110, 120, 130, 140, are arranged such that the first, second, third, and fourth reflective polarizers 115, 125, 135, 145, are aligned in an “X” shape. Further, the first imager surface 126 and the input surface 136 are adjacent, and the second imager surface 146 is disposed opposite the output surface 116.

A first imager 170 is disposed facing the first imager surface 126 and a second imager 180 is disposed facing the second imager surface 146 such that an unpolarized input light 151 that enters the input surface 136 from an illumination optic 150, exits the output surface 116 as a first imaged light 155 having the first polarization direction 195 (that is, the s-polarization direction in FIG. 1), and a second imaged light 154 having the second orthogonal polarization direction (that is, the p-polarization direction in FIG. 1).

Unpolarized input light 151 enters third PBS 130 through input surface 136, intercepts third reflective polarizer 135, and is split into transmitted p-polarized light 152 and reflected s-polarized light 153. Transmitted p-polarized light 152 passes into fourth PBS 140, reflects from fourth reflective polarizer 145, exits fourth PBS 140 through second imager surface 146, and is reflected from second imager 180 as second imaged s-polarized light 154. Second imaged s-polarized light 154 enters fourth PBS 140 through second imager surface 146, passes through fourth reflective polarizer 145, enters first PBS 110, passes through first reflective polarizer 115, exits output surface 116, and enters projection optics 160 as second imaged s-polarized light 154.

Reflected s-polarized light 153 passes into second PBS 120, reflects from second reflective polarizer 125, exits second PBS 120 through first imager surface 126 and reflects from first imager 170 as first imaged p-polarized light 155. First imaged p-polarized light 155 enters second PBS 120 through first imager surface 126, passes through second reflective polarizer 125, enters first PBS 110, reflects from first reflective polarizer 115, exits output surface 116, and enters projection optics 160 as first imaged p-polarized light 155. Projection optics 160 for projecting an image to a projection screen have been described elsewhere, and are generally well known to those of skill in the art.

Illumination optics 150 generally provide a collimated and uniform light that can be efficiently used within the projector 100 and projected through to the projection optics 160. Illumination optics 150 can include any of the light sources described elsewhere, and can be associated with a variety of optical elements including collimators and color combiners that are suitable for use in the present disclosure including those described, for example, in co-pending U.S. Patent Application Serial Nos. 61/385,237, 61/385,241, 61/385,248, 61/485,165; PCT Patent Publication Nos. WO2009/085856 entitled “Light Combiner”, WO2009/086310 entitled “Light Combiner”, WO2009/139798 entitled “Optical Element and Color Combiner”, WO2009/139799 entitled “Optical Element and Color Combiner”; and also in co-pending PCT Patent Application Nos. US2009/062939 entitled “Polarization Converting Color Combiner”, US2009/063779 entitled “High Durability Color Combiner”, US2009/064927 entitled “Color Combiner”, and US2009/064931 entitled “Polarization Converting Color Combiner”; published U. S. Patent Application Nos. US2010/0277796, US2011/0007392, US2011/0216396; published PCT Patent Application No. WO2011/034810; and also in U.S. Pat. No. 7,821,713.

First imaged p-polarized light 155 and second imaged s-polarized light 154 exit projection optics 160 as portions of projected light 165 which can be: a 3D stereoscopic projection without time-sequencing, using different polarization states for images sent to each eye; an effectively doubled brightness image for identical images on each of the two imagers; two completely different video contents viewable on the same screen using different polarization state glasses; two different video contents, one on each polarization state, projected onto a reflective polarizer, thereby separating the two contents so that they can be displayed, for example, side-by-side or one on top of the other; or time sequenced images combined with active goggles, so that two different 3D contents are projected simultaneously by the same device on to the same (or, in combination with the above embodiment, different) screens, as described elsewhere.

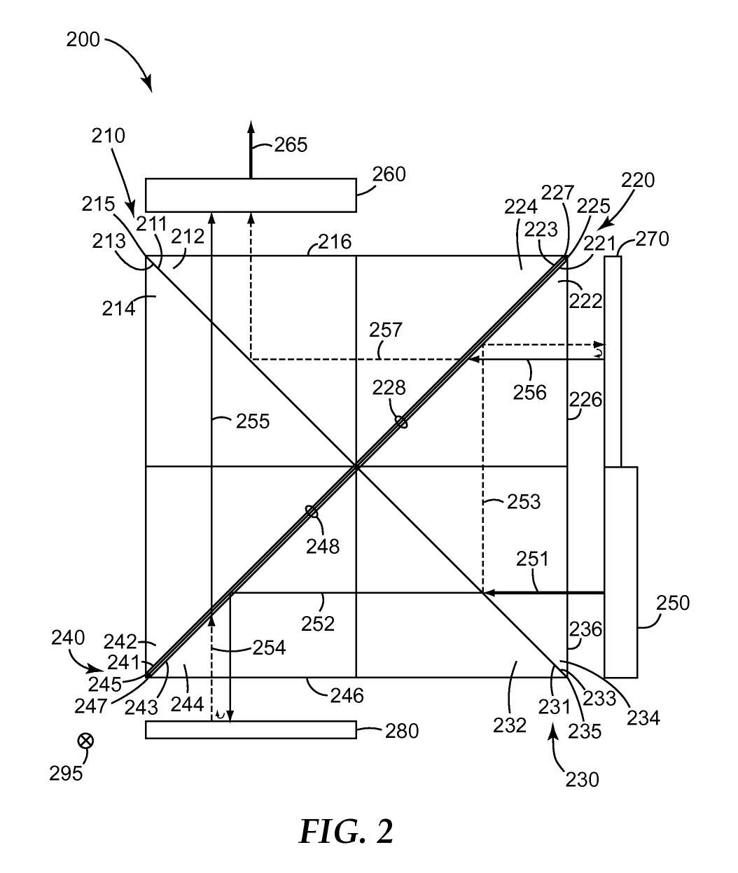

FIG. 2 shows a cross-sectional schematic of a two imager projector 200 according to one aspect of the disclosure. Projector 200 includes a first polarizing beam splitter (PBS) 210 that includes a first prism 212 having a first diagonal surface 211 and an output surface 216, a second prism 214 having a second diagonal surface 213, and a first reflective polarizer 215 disposed between the first diagonal surface 211 and the second diagonal surface 213. The first reflective polarizer 215 is aligned to a first polarization direction 295. In the embodiment shown in FIG. 2, the first polarization direction 295 is shown to be perpendicular to the page, and aligned to the first polarization direction 295 is intended to mean that the first reflective polarizer 215 is aligned to pass p-polarized light and reflect s-polarized light, as described elsewhere.

Projector 200 further includes a second PBS 220 that includes a third prism 222 having a third diagonal surface 221 and a first imager surface 226, and a fourth prism 224 having a fourth diagonal surface 223. Second PBS 220 further includes a second reflective polarizer 225 disposed adjacent the third diagonal surface 221 and a first half-wave retarder 227 disposed adjacent the fourth diagonal surface 223. The second reflective polarizer 225 is aligned to the first polarization direction, such that p-polarized light passes through the second reflective polarizer 225 and s-polarized light reflects from the second reflective polarizer 225. The second reflective polarizer 225 and the first half-wave retarder 227 form a first rotating reflective polarizer laminate 228. In some cases, the first half-wave retarder 227 in the first rotating reflective polarizer laminate 228 can be aligned at any desired angle to the first polarization direction, such as 45 degrees, as described elsewhere. In some cases, the first half-wave retarder 227 can be instead replaced by two quarter-wave retarders (not shown) aligned at an angle to the first polarization direction 295, as described elsewhere. In other cases, these reflective polarizers may be aligned to other angles that best optimize the polarization rotation efficiency.

Projector 200 still further includes a third PBS 230 that includes a fifth prism 232 having a fifth diagonal surface 231, a sixth prism 234 having a sixth diagonal surface 233, an input surface 236, and a third reflective polarizer 235 disposed between the fifth diagonal surface 231 and the sixth diagonal surface 233. The third reflective polarizer 235 is aligned to the first polarization direction, such that p-polarized light passes through the third reflective polarizer 235 and s-polarized light reflects from the third reflective polarizer 235, as described elsewhere.

Projector 200 still further includes a fourth PBS 240 that includes a seventh prism 242 having a seventh diagonal surface 241, an eighth prism 244 having a eighth diagonal surface 243, and a second imager surface 246. Fourth PBS 240 further includes a fourth reflective polarizer 245 disposed adjacent the seventh diagonal surface 241 and a second half-wave retarder 247 disposed adjacent the eighth diagonal surface 243. The fourth reflective polarizer 245 is aligned to the first polarization direction, such that p-polarized light passes through the fourth reflective polarizer 245 and s-polarized light reflects from the fourth reflective polarizer 245. The fourth reflective polarizer 245 and the second half-wave retarder 247 form a second rotating reflective polarizer laminate 248. In some cases, the second half-wave retarder 247 in the second rotating reflective polarizer laminate 248 can be aligned at any desired angle to the first polarization direction, such as 45 degrees, as described elsewhere. In some cases, the second half-wave retarder 247 can be instead replaced by two quarter-wave retarders (not shown) aligned at an angle to the first polarization direction 295, as described elsewhere.

The first, second, third, and fourth PBS 210, 220, 230, 240, are arranged such that the first, second, third, and fourth reflective polarizers 215, 225, 235, 245, are aligned in an “X” shape. Further, the first imager surface 226 and the input surface 236 are adjacent, and the second imager surface 246 is disposed opposite the output surface 216.

A first imager 270 is disposed facing the first imager surface 226 and a second imager 280 is disposed facing the second imager surface 246 such that an unpolarized input light 251 that enters the input surface 236 from an illumination optics 250, exits the output surface 216 as a first imaged light 257 having the second orthogonal polarization direction (that is, the s-polarization direction in FIG. 2), and a second imaged light 255 having the first polarization direction (that is, the p-polarization direction in FIG. 2).

Unpolarized input light 251 enters third PBS 230 through input surface 236, intercepts third reflective polarizer 235, and is split into transmitted p-polarized light 252 and reflected s-polarized light 253. Transmitted p-polarized light 252 passes into fourth PBS 240, passes through second half-wave retarder 247 rotating to s-polarized light that reflects from fourth reflective polarizer 245, passes again through second half-wave retarder 247 rotating back to p-polarized light, exits fourth PBS 240 through second imager surface 246, and is reflected from second imager 280 as second imaged s-polarized light 254. Second imaged s-polarized light 254 enters fourth PBS 240 through second imager surface 246, passes through half-wave retarder 247 rotating to second imaged p-polarized light 255 that passes through fourth reflective polarizer 245, enters first PBS 210, passes through first reflective polarizer 215, exits output surface 216, and enters projection optics 260 as second imaged p-polarized light 255.

Reflected s-polarized light 253 passes into second PBS 220, reflects from second reflective polarizer 225, exits second PBS 220 through first imager surface 226 and reflects from first imager 270 as first imaged p-polarized light 256. First imaged p-polarized light 256 enters second PBS 220 through first imager surface 226, passes through second reflective polarizer 225, passes through first half-wave retarder 227 rotating to first imaged s-polarized light 257, enters first PBS 210, reflects from first reflective polarizer 215, exits first output surface 216, and enters projection optics 260 as first imaged s-polarized light 257.

First imaged s-polarized light 257 and second imaged p-polarized light 255 exit projection optics 260 as portions of projected light 265 which can be: a 3D stereoscopic projection without time-sequencing, using different polarization states for images sent to each eye; an effectively doubled brightness image for identical images on each of the two imagers; two completely different video contents viewable on the same screen using different polarization state glasses; two different video contents, one on each polarization state, projected onto a reflective polarizer, thereby separating the two contents so that they can be displayed, for example, side-by-side or one on top of the other; or time sequenced images combined with active goggles, so that two different 3D contents are projected simultaneously by the same device on to the same (or, in combination with the above embodiment, different) screens, as described elsewhere.

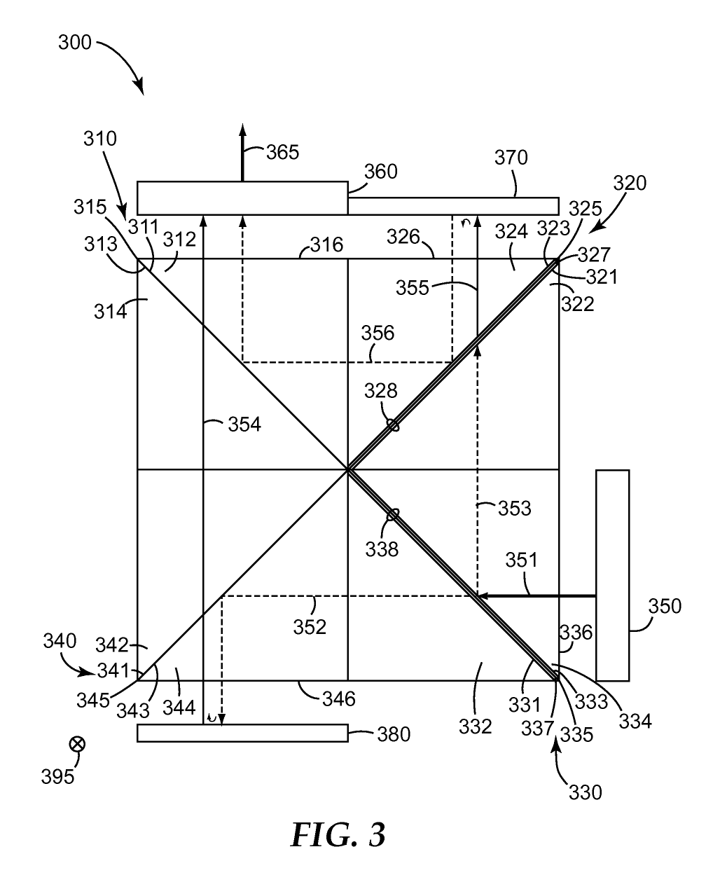

FIG. 3 shows a cross-sectional schematic of a two imager projector 300 according to one aspect of the disclosure. Projector 300 includes a first polarizing beam splitter (PBS) 310 that includes a first prism 312 having a first diagonal surface 311 and an output surface 316, a second prism 314 having a second diagonal surface 313, and a first reflective polarizer 315 disposed between the first diagonal surface 311 and the second diagonal surface 313. The first reflective polarizer 315 is aligned to a first polarization direction 395. In the embodiment shown in FIG. 3, the first polarization direction 395 is shown to be perpendicular to the page, and aligned to the first polarization direction 395 is intended to mean that the first reflective polarizer 315 is aligned to pass p-polarized light and reflect s-polarized light, as described elsewhere.

Projector 300 further includes a second PBS 320 that includes a third prism 322 having a third diagonal surface 321. Second PBS 320 further includes a fourth prism 324 having a fourth diagonal surface 323 and a first imager surface 326. Second PBS 320 still further includes a second reflective polarizer 325 disposed adjacent the fourth diagonal surface 323 and a first half-wave retarder 327 disposed adjacent the third diagonal surface 321. The second reflective polarizer 325 is aligned to the first polarization direction, such that p-polarized light passes through the second reflective polarizer 325 and s-polarized light reflects from the second reflective polarizer 325. The second reflective polarizer 325 and the first half-wave retarder 327 form a first rotating reflective polarizer laminate 328. In some cases, the first half-wave retarder 327 in the first rotating reflective polarizer laminate 328 can be aligned at any desired angle to the first polarization direction, such as 45 degrees, as described elsewhere. In some cases, the first half-wave retarder 327 can be instead replaced by two quarter-wave retarders (not shown) aligned at an angle to the first polarization direction 395, as described elsewhere.

Projector 300 still further includes a third PBS 330 that includes a fifth prism 332 having a fifth diagonal surface 331, a sixth prism 334 having a sixth diagonal surface 333, and an input surface 336. Third PBS 330 further includes a third reflective polarizer 335 disposed adjacent the sixth diagonal surface 333 and a second half-wave retarder 337 disposed adjacent the fifth diagonal surface 331. The third reflective polarizer 335 is aligned to the first polarization direction, such that p-polarized light passes through the third reflective polarizer 335 and s-polarized light reflects from the third reflective polarizer 335. The third reflective polarizer 335 and the second half-wave retarder 337 form a second rotating reflective polarizer laminate 338. In some cases, the second half-wave retarder 337 in the second rotating reflective polarizer laminate 338 can be aligned at any desired angle to the first polarization direction, such as 45 degrees, as described elsewhere. In some cases, the second half-wave retarder 337 can be instead replaced by two quarter-wave retarders (not shown) aligned at an angle to the first polarization direction 395, as described elsewhere.

Projector 300 still further includes a fourth PBS 340 that includes a seventh prism 342 having a seventh diagonal surface 341, a sixth prism 344 having an eighth diagonal surface 343, a second imager surface 346, and a fourth reflective polarizer 345 disposed between the seventh diagonal surface 341 and the eighth diagonal surface 343. The fourth reflective polarizer 345 is aligned to the first polarization direction, such that p-polarized light passes through the fourth reflective polarizer 345 and s-polarized light reflects from the fourth reflective polarizer 345, as described elsewhere.

The first, second, third, and fourth PBS 310, 320, 330, 340, are arranged such that the first, second, third, and fourth reflective polarizers 315, 325, 335, 345, are aligned in an “X” shape. Further, the first imager surface 326 and the output surface 316 are adjacent, and the second imager surface 346 is disposed opposite the output surface 316.

A first imager 370 is disposed facing the first imager surface 326 and a second imager 380 is disposed facing the second imager surface 346 such that an unpolarized input light 351 that enters the input surface 336 from an illumination optics 350, exits the output surface 316 as a first imaged light 356 having the second orthogonal polarization direction (that is, the s-polarization direction in FIG. 3), and a second imaged light 354 having the first polarization direction (that is, the p-polarization direction in FIG. 3).

Unpolarized input light 351 enters third PBS 330 through input surface 336, intercepts third reflective polarizer 335, and is split into transmitted p-polarized light which passes through second half-wave retarder 337 as transmitted s-polarized light 352, and reflected s-polarized light 353. Transmitted s-polarized light 352 passes into fourth PBS 340, reflects from fourth reflective polarizer 345, exits fourth PBS 340 through second imager surface 346, and is reflected from second imager 380 as second imaged p-polarized light 354. Second imaged p-polarized light 354 enters fourth PBS 340 through second imager surface 346, passes through fourth reflective polarizer 345, enters first PBS 310, passes through first reflective polarizer 315, exits output surface 316, and enters projection optics 360 as second imaged p-polarized light 354.

Reflected s-polarized light 353 passes into second PBS 320, passes through first half-wave retarder 327 rotating to p-polarized light 355 that passes through second reflective polarizer 325, exits second PBS 320 through first imager surface 326 and reflects from first imager 370 as first imaged s-polarized light 356. First imaged s-polarized light 356 enters second PBS 320 through first imager surface 326, reflects from second reflective polarizer 325, enters first PBS 310, reflects from first reflective polarizer 315, exits first output surface 316, and enters projection optics 360 as first imaged s-polarized light 356.

First imaged s-polarized light 356 and second imaged p-polarized light 354 exit projection optics 360 as portions of projected light 365 which can be: a 3D stereoscopic projection without time-sequencing, using different polarization states for images sent to each eye; an effectively doubled brightness image for identical images on each of the two imagers; two completely different video contents viewable on the same screen using different polarization state glasses; two different video contents, one on each polarization state, projected onto a reflective polarizer, thereby separating the two contents so that they can be displayed, for example, side-by-side or one on top of the other; or time sequenced images combined with active goggles, so that two different 3D contents are projected simultaneously by the same device on to the same (or, in combination with the above embodiment, different) screens, as described elsewhere.

Because the imaged light reflected from an imager is subsequently reflected from the reflective polarizers, the reflective polarizers must be sufficiently flat to maintain appropriate resolution of the image. Techniques for providing sufficiently flat reflective polarizers can be found, for example, in co-pending U.S. Patent Application Ser. No. 61/564,172 entitled METHOD OF MAKING POLARIZING BEAM SPLITTERS PROVIDING HIGH RESOLUTION IMAGES AND SYSTEMS UTILIZING SUCH BEAM SPLITTERS (Attorney Docket No. 68016US002) filed Nov. 28, 2011. Flatness can be quantified by the standard roughness parameters Ra (the average of the absolute value of the vertical deviation of the surface from the mean), Rq (the root mean squared average of the vertical deviation of the surface from the mean), and Rz (the average distance between the highest peak and lowest valley in each sampling length). Specifically, the reflective polarizer preferably has a surface roughness Ra of less than 45 nm or a surface roughness Rq of less than 80 nm, and more preferably has a surface roughness Ra of less than 40 nm or a surface roughness Rq of less than 70 nm, and even more preferably has a surface roughness Ra of less than 35 nm or a surface roughness Rq of less than 55 nm. In the projection light paths, the respective transmitting polarizers serve as “cleanup” polarizers for the image reflecting polarizers. This provides the potential for improved contrast compared to single PBS reflective imaging approaches.

Following are a list of embodiments of the present disclosure.

Item 1 is an imaging device, comprising: a first polarizing beam splitter (PBS) having an output surface and a first reflective polarizer aligned to a first polarization direction; a second PBS having a first imager surface and a second reflective polarizer aligned to an orthogonal second polarization direction; a third PBS having an input surface and a third reflective polarizer aligned to the second orthogonal polarization direction; a fourth PBS having a second imager surface and a fourth reflective polarizer aligned to the first polarization direction, the first through fourth PBS arranged such that the first through fourth reflective polarizers are aligned in an X shape, the first imager surface adjacent the input surface, and the second imager surface opposite the output surface; a first imager disposed facing the first imager surface; and a second imager disposed facing the second imager surface, wherein an unpolarized input light entering the input surface exits the output surface as a first imaged light having the first polarization direction and a second imaged light having the second orthogonal polarization direction.

Item 2 is the imaging device of item 1, wherein the first polarization direction of the input light reflects from the second imager as the second imaged light having the second polarization direction, and the second polarization direction of the input light reflects from the first imager as the first imaged light having the first polarization direction.

Item 3 is the imaging device of item 1 or item 2, wherein the first and second orthogonal polarization directions comprise linear polarization.

Item 4 is the imaging device of item 1 to item 3, wherein each of the reflective polarizers are disposed as pellicles or as interior surfaces of a PBS.

Item 5 is the imaging device of item 1 to item 4, wherein the first imager and the second imager each comprise a portion of a stereoscopic image.

Item 6 is the imaging device of item 1 to item 4, wherein the first imager and the second imager comprise a liquid crystal imager, a liquid crystal on silicon (LCOS) imager, a digital micromirror imager, or a combination thereof.

Item 7 is the imaging device of item 6, wherein the digital micromirror imager further comprises a quarter-wave retarder.

Item 8 is the imaging device of item 1 to item 7, wherein the input light comprises a time-sequenced color input.

Item 9 is the imaging device of item 1 to item 8, wherein the first and second imagers in combination comprise an alternating time-sequenced first stereoscopic image and second stereoscopic image.

Item 10 is an imaging device, comprising: a first polarizing beam splitter (PBS) having an output surface and a first reflective polarizer; a second PBS having a first imager surface, a second reflective polarizer, and a first adjacent half-wave retarder; a third PBS having an input surface and a third reflective polarizer; a fourth PBS having a second imager surface, a fourth reflective polarizer, and a second adjacent half-wave retarder, wherein the first through fourth PBS are arranged such that the first through fourth reflective polarizers are each aligned to a first polarization direction and form an X shape, the first imager surface adjacent the input surface, and the second imager surface opposite the output surface; a first imager disposed facing the first imager surface; and a second imager disposed facing the second imager surface, wherein an unpolarized input light entering the input surface, exits the output surface as a second imaged light having the first polarization direction and a first imaged light having a second polarization direction orthogonal to the first polarization direction.

Item 11 is the imaging device of item 10, wherein the first polarization direction of the input light reflects from the second imager as the second imaged light having the second polarization direction, and the second polarization direction of the input light reflects from the first imager as the first imaged light having the first polarization direction.

Item 12 is the imaging device of item 10 or item 11, wherein the first and second orthogonal polarization directions comprise linear polarization.

Item 13 is the imaging device of item 10 to item 12, wherein each of the reflective polarizers are disposed as pellicles or as interior surfaces of a PBS.

Item 14 is the imaging device of item 10 to item 13, wherein the first imager and the second imager each comprise a portion of a stereoscopic image.

Item 15 is the imaging device of item 10 to item 14, wherein the first imager and the second imager comprise a liquid crystal imager, a liquid crystal on silicon (LCOS) imager, a digital micromirror imager, or a combination thereof.

Item 16 is the imaging device of item 15, wherein the digital micromirror imager further comprises a quarter-wave retarder.

Item 17 is the imaging device of item 10 to item 16, wherein the input light comprises a time-sequenced color input.

Item 18 is the imaging device of item 10 to item 17, wherein the first and second imagers in combination comprise an alternating time-sequenced first stereoscopic image and second stereoscopic image.

Item 19 is the imaging device of item 10 to item 18, wherein each of the first and the second half-wave retarder are independently aligned at an angle to the first polarization direction.

Item 20 is the imaging device of item 10 to item 19, wherein at least one of the first and the second half-wave retarders comprise two quarter-wave retarders.

Item 21 is an imaging device, comprising: a first polarizing beam splitter (PBS) having an output surface and a first reflective polarizer; a second PBS having a first imager surface, a second reflective polarizer, and a first adjacent half-wave retarder; a third PBS having an input surface, a third reflective polarizer, and a second adjacent half-wave retarder; a fourth PBS having a second imager surface and a fourth reflective polarizer, wherein the first through fourth PBS are arranged such that the first through fourth reflective polarizers are each aligned to a first polarization direction and form an X shape, the first imager surface adjacent the output surface, and the second imager surface opposite the output surface; a first imager disposed facing the first imager surface; and a second imager disposed facing the second imager surface, wherein an unpolarized input light entering the input surface, exits the output surface as a second imaged light having the first polarization direction and a first imaged light having a second polarization direction orthogonal to the first polarization direction.

Item 22 is the imaging device of item 21, wherein the first polarization direction of the input light reflects from the first imager as the first imaged light having the second polarization direction, and the second polarization direction of the input light reflects from the second imager as the first imaged light having the first polarization direction.

Item 23 is the imaging device of item 21 or item 22, wherein the first and second orthogonal polarization directions comprise linear polarization.

Item 24 is the imaging device of item 21 to item 23, wherein each of the reflective polarizers are disposed as pellicles or as interior surfaces of a PBS.

Item 25 is the imaging device of item 21 to item 24, wherein the first imager and the second imager each comprise a portion of a stereoscopic image.

Item 26 is the imaging device of item 21 to item 25, wherein the first imager and the second imager comprise a liquid crystal imager, a liquid crystal on silicon (LCOS) imager, a digital micromirror imager, or a combination thereof.

Item 27 is the imaging device of item 26, wherein the digital micromirror imager further comprises a quarter-wave retarder.

Item 28 is the imaging device of item 21 to item 27, wherein the input light comprises a time-sequenced color input.

Item 29 is the imaging device of item 21 to item 28, wherein the first and second imagers in combination comprise an alternating time-sequenced first stereoscopic image and second stereoscopic image.

Item 30 is the imaging device of item 21 to item 29, wherein each of the first and the second half-wave retarder are independently aligned at an angle to the first polarization direction.

Item 31 is the imaging device of item 21 to item 30, wherein at least one of the first and the second half-wave retarders comprise two quarter-wave retarders.

Item 32 is a projection system, comprising: the imaging device according to item 1 to item 31; an input light source capable of injecting light into the input surface; and projection optics disposed to project light exiting from the output surface to a projection screen.

Item 33 is the imaging device of item 1 to item 31, wherein each reflective polarizer comprises a reflective polarizer laminate having either a pair of reflective polarizers, or an absorptive polarizer sandwiched between a pair of reflective polarizers, each aligned to the same polarization direction.

Unless otherwise indicated, all numbers expressing feature sizes, amounts, and physical properties used in the specification and claims are to be understood as being modified by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

All references and publications cited herein are expressly incorporated herein by reference in their entirety into this disclosure, except to the extent they may directly contradict this disclosure. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. An imaging device, comprising:
a first polarizing beam splitter (PBS) having an output surface and a first reflective polarizer aligned to a first polarization direction;
a second PBS having a first imager surface and a second reflective polarizer aligned to an orthogonal second polarization direction;
a third PBS having an input surface and a third reflective polarizer aligned to the second orthogonal polarization direction;
a fourth PBS having a second imager surface and a fourth reflective polarizer aligned to the first polarization direction, the first through fourth PBS arranged such that the first through fourth reflective polarizers are aligned in an X shape, the first imager surface adjacent the input surface, and the second imager surface opposite the output surface;
a first imager disposed facing the first imager surface; and
a second imager disposed facing the second imager surface,
wherein an unpolarized input light entering the input surface exits the output surface as a first imaged light having the first polarization direction and a second imaged light having the second orthogonal polarization direction.

2. The imaging device of claim 1, wherein the first polarization direction of the input light reflects from the second imager as the second imaged light having the second polarization direction, and the second polarization direction of the input light reflects from the first imager as the first imaged light having the first polarization direction.

3. The imaging device of claim 1, wherein the first and second orthogonal polarization directions comprise linear polarization.

4. The imaging device of claim 1, wherein each of the reflective polarizers are disposed as pellicles or as interior surfaces of a PBS.

5. The imaging device of claim 1, wherein the first imager and the second imager each comprise a portion of a stereoscopic image.

6. The imaging device of claim 1, wherein the first imager and the second imager comprise a liquid crystal imager, a liquid crystal on silicon (LCOS) imager, a digital micromirror imager, or a combination thereof.

7. The imaging device of claim 6, wherein the digital micromirror imager further comprises a quarter-wave retarder.

8. The imaging device of claim 1, wherein the input light comprises a time-sequenced color input.

9. The imaging device of claim 1, wherein the first and second imagers in combination comprise an alternating time-sequenced first stereoscopic image and second stereoscopic image.

10. An imaging device, comprising:
a first polarizing beam splitter (PBS) having an output surface and a first reflective polarizer;
a second PBS having a first imager surface, a second reflective polarizer, and a first adjacent half-wave retarder;
a third PBS having an input surface and a third reflective polarizer;
a fourth PBS having a second imager surface, a fourth reflective polarizer, and a second adjacent half-wave retarder,
wherein the first through fourth PBS are arranged such that the first through fourth reflective polarizers are each aligned to a first polarization direction and form an X shape, the first imager surface adjacent the input surface, and the second imager surface opposite the output surface;
a first imager disposed facing the first imager surface; and
a second imager disposed facing the second imager surface,
wherein an unpolarized input light entering the input surface, exits the output surface as a second imaged light having the first polarization direction and a first imaged light having a second polarization direction orthogonal to the first polarization direction.

11. The imaging device of claim 10, wherein the first polarization direction of the input light reflects from the second imager as the second imaged light having the second polarization direction, and the second polarization direction of the input light reflects from the first imager as the first imaged light having the first polarization direction.

12. The imaging device of claim 10, wherein the first and second orthogonal polarization directions comprise linear polarization.

13. The imaging device of claim 10, wherein each of the reflective polarizers are disposed as pellicles or as interior surfaces of a PBS.

14. The imaging device of claim 10, wherein the first imager and the second imager each comprise a portion of a stereoscopic image.

15. The imaging device of claim 10, wherein the first imager and the second imager comprise a liquid crystal imager, a liquid crystal on silicon (LCOS) imager, a digital micromirror imager, or a combination thereof.

16. The imaging device of claim 15, wherein the digital micromirror imager further comprises a quarter-wave retarder.

17. The imaging device of claim 10, wherein the input light comprises a time-sequenced color input.

18. The imaging device of claim 10, wherein the first and second imagers in combination comprise an alternating time-sequenced first stereoscopic image and second stereoscopic image.

19. The imaging device of claim 10, wherein each of the first and the second half-wave retarder are independently aligned at an angle to the first polarization direction.

20. The imaging device of claim 10, wherein at least one of the first and the second half-wave retarders comprise two quarter-wave retarders.

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)
